(19) United States
(12) Patent Application Publication
(10) Pub. No.: US 2007/0057731 A1
(43) Pub. Date: Mar. 15, 2007

(54) On-chip harmonic termination for RF power amplifier applications

(76) Inventor: Phuong T. Le, Goodyear, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/229,112

(22) Filed: Sep. 15, 2005

(51) Int. Cl. H03F 3/191

(52) U.S. Cl. 330/302; 330/305; 330/307

(57) ABSTRACT

A radio frequency (“RF”) amplifier as disclosed herein includes an on-chip power transistor formed on a substrate and an on-chip harmonic termination formed on the same substrate. The on-chip harmonic termination is configured to provide a short-circuit termination for even harmonics of the RF output signal and to provide an open-circuit termination for odd harmonics of the RF output signal. The on-chip harmonic termination employs tunable inductance elements and tunable capacitor elements to achieve the desired resonant characteristics. In one example embodiment, the on-chip harmonic termination utilizes conductive wire bonds as the tunable inductance elements, and arrays or banks of on-chip capacitors as the tunable capacitance elements.

### TECHNICAL FIELD

The present invention relates generally to electronic components. More particularly, the present invention relates to an on-chip harmonic termination suitable for use with radio frequency (“RF”) power amplifiers.

### BACKGROUND

The prior art is replete with electronic devices and components designed for high frequency applications. For example, RF power amplifiers are typically found in wireless communication devices and subsystems such as wireless base stations, wireless handsets, WLAN components, and the like. RF power amplifiers operate more efficiently with harmonic impedances terminating properly such that harmonic components of the RF output signal are suppressed. Historically, harmonic terminations for on-chip RF power amplifiers have been implemented off-chip, for example, on a printed circuit board upon which the RF power amplifier chip is mounted.

In many practical applications, the need for component integration will increase as module sizes decrease. In accordance with the current trend toward miniaturization, a smaller device footprint is desirable, especially if such a smaller footprint can be achieved without a significant increase in manufacturing cost or complexity. Unfortunately, off-chip harmonic terminations inherently contribute to the overall size of the devices and require additional manufacturing steps that can increase the overall cost of the devices.

Accordingly, it is desirable to have a compact, low cost, on-chip RF power amplifier that is integrated with an on-chip harmonic termination. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

A more complete understanding of the present invention may be derived by referring to the detailed description and claims when considered in conjunction with the following figures, wherein like reference numbers refer to similar elements throughout the figures.

FIG. 1 is a schematic representation of an RF electronic device configured in accordance with an example embodiment of the invention;

FIG. 2 is a circuit diagram of a transistor and a harmonic termination configured in accordance with an example embodiment of the invention;

FIG. 3 is a top view of an on-chip harmonic termination layout configured in accordance with an example embodiment of the invention;

FIG. 4 is a top view of an RF electronic device configured in accordance with an example embodiment of the invention; and

FIG. 5 is a top view of an RF electronic device configured in accordance with another example embodiment of the invention.

### DETAILED DESCRIPTION

The following detailed description is merely illustrative in nature and is not intended to limit the invention or the application and uses of the invention. Furthermore, there is no intention to be bound by any expressed or implied theory presented in the preceding technical field, background, brief summary or the following detailed description.

The invention may be described herein in terms of functional and/or schematic components. It should be appreciated that such components may be realized in any number of practical ways. For example, an embodiment of the invention may employ various elements, e.g., conductive traces, wire bonds, integrated passive devices, semiconductor substrate materials, dielectric materials, or the like, which may have characteristics or properties known to those skilled in the art. In addition, those skilled in the art will appreciate that the present invention may be practiced in conjunction with any number of practical RF circuit topologies and applications and that the RF amplifier circuits described herein are merely example applications for the invention.

For the sake of brevity, conventional techniques related to RF circuit design, RF signal propagation, RF impedance matching, semiconductor process technology, harmonic filter design, integrated passive device fabrication, and other aspects of the circuits (and the individual operating components of the circuits) may not be described in detail herein. Furthermore, the connecting lines shown in the various figures contained herein are intended to represent example functional relationships and/or physical couplings between the various elements. It should be noted that many alternative or additional functional relationships or physical connections may be present in a practical embodiment.

As used herein, a “node” means any internal or external reference point, connection point, junction, signal line, conductive element, or the like, at which a given signal, logic level, voltage, data pattern, current, or quantity is present. Furthermore, two or more nodes may be realized by one physical element (and two or more signals can be multiplexed, modulated, or otherwise distinguished even though received or output at a common mode).

The following description refers to nodes or features being “connected” or “coupled” together. As used herein, unless expressly stated otherwise, “connected” means that one node/feature is directly joined to (or directly communicates with) another node/feature, and not necessarily mechanically. As used herein, unless expressly stated otherwise, “coupled” means that one node/feature is directly or indirectly joined to (or directly or indirectly communicates with) another node/feature, and not necessarily mechanically. Thus, although the figures depict example arrangements of elements, additional intervening elements, devices, features, or components may be present in an actual embodiments (assuming that the functionality of the circuits are not adversely affected).

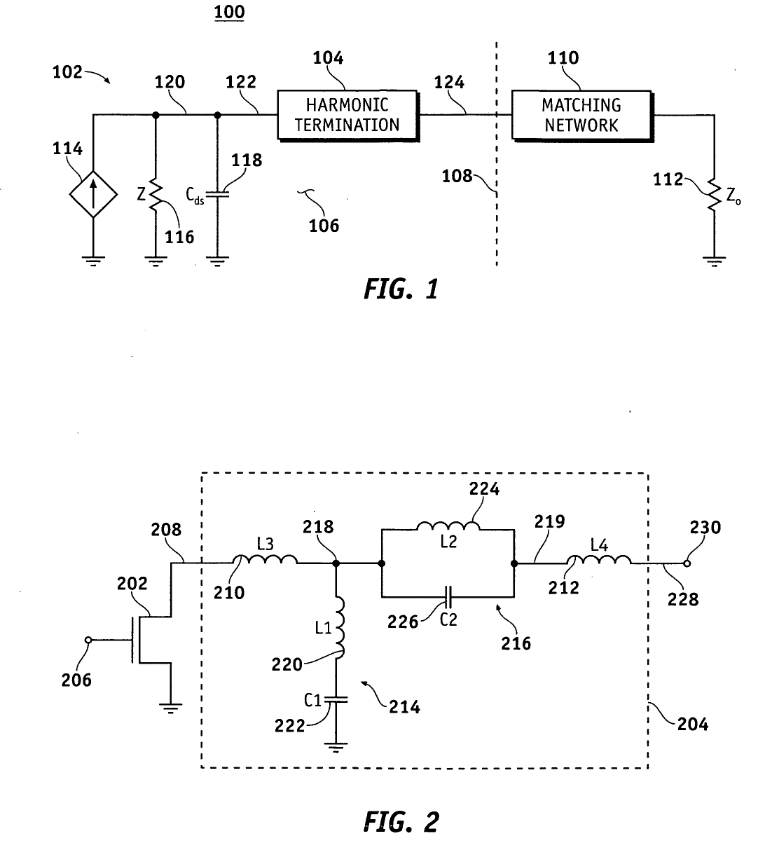

FIG. 1 is a schematic representation of an RF electronic device 100 configured in accordance with an example embodiment of the invention. Device 100 generally includes a transistor 102 and a harmonic termination 104, both of which are formed on a common semiconductor substrate 106 (a semiconductor substrate is a substrate that includes semiconductor material). As shown and described herein, device 100 may be realized as a Class-F RF power amplifier suitable for use in any number of practical applications, e.g., wireless handset devices, wireless base stations, WLAN components, or any device, system, or subsystem that utilizes RF power amplifiers. For example, device 100 may be suitably configured to operate with frequencies in the GHz range (where the actual maximum operating frequency may depend upon practical device manufacturing limitations). The invention, however, is not limited to Class-F amplifiers, and the subject matter described herein may be equivalently applied to other amplifier types. RF amplifiers and transistors are generally known and, for the sake of brevity, details of their operation will not be described herein.

In practice, electronic device 100 can be fabricated using any suitable semiconductor manufacturing process technology. For example, electronic device 100 may be manufactured using an appropriate laterally diffused metal-oxide semiconductor (LDMOS) process. Alternatively, electronic device 100 may be manufactured using a suitable HBT process, a suitable GaAs process, or the like. Furthermore, electronic device 100 may utilize transistor types other than FETs as described herein, including, without limitation: BJT; HBT; HEMT; and GaAs.

As used herein, components, elements, and features that are integrally fabricated on semiconductor substrate 106, located on semiconductor substrate 106, and/or mounted on semiconductor substrate 106 are considered to be “on-chip,” while other components, elements, and features are considered to be “off-chip.” In this regard, a dashed line 108 in FIG. 1 separates the on-chip elements of device 100 from the off-chip elements of device 100. Elements to the left of dashed line 108 are on-chip and elements to the right of dashed line 108 are off-chip. In this example, the off-chip elements include an output matching network 110 and an output impedance 112. In a practical embodiment, device 100 may be realized as an integrated circuit chip mounted to a printed circuit board or card, and the off-chip elements may be realized as one or more separate integrated circuit chips, surface mount components, discrete devices, and/or conductive traces located on the printed circuit board or card.

In FIG. 1, transistor 102 is modeled as a current source 114 in parallel with an impedance 116 and a drain-source capacitance 118. Impedance 116 is an output load impedance that is inherent to the device structure of transistor 102, and drain-source capacitance 118 is a small capacitance that is inherent to the device structure of transistor 102. In practical embodiments, device 100 is an RF power amplifier, and transistor 102 is suitably configured and controlled to provide an RF output signal at a transistor output node 120. In this example, transistor output node 120 corresponds to a common node shared by harmonic termination 104, current source 114, impedance 116, and drain-source capacitance 118.

The on-chip harmonic termination 104 includes a termination input node 122 coupled to transistor output node 120, which enables harmonic termination 104 to receive the RF output signal generated by transistor 102, and a termination output node 124 for providing a terminated RF output signal. In the practical embodiment described herein, termination input node 122 corresponds to transistor output node 120. Harmonic termination 104 is suitably tuned and configured to provide a short-circuit termination for even harmonics of the RF output signal, and to provide an open-circuit termination for odd harmonics of the RF output signal. In practice, the tuning of harmonic termination 104 considers impedance 116, drain-source capacitance 118, and the operating frequency or frequency range of device 100. In this manner, harmonic termination 104 improves the efficiency and output power of device 100. The on-chip nature of device 100 allows harmonic termination 104 to be physically located close to transistor 102, thus reducing the physical size of device 100.

The off-chip matching network 110 may be realized with any number of electronic devices or components, such as resistors, capacitors, or inductors. Using known RF impedance matching techniques, matching network 110 is suitably designed to match output impedance 112, resulting in an efficient transmission of RF power to the off-chip components. In many practical wireless applications, output impedance 112 is 50 Ohms, and matching network 110 is tuned accordingly.

FIG. 2 is a circuit diagram of a transistor 202 and a harmonic termination 204 configured in accordance with an example embodiment of the invention. The circuit topology shown in FIG. 2 may be utilized in connection with RF electronic device 100 shown in FIG. 1. All of the elements shown in FIG. 2 (with the possible exception of the L4 inductance element) are on-chip elements located on the same substrate or chip. As described in more detail below, the L4 inductance element may be realized as a wire bond connected between an on-chip element and an off-chip element.

Transistor 202 includes a transistor input 206 and a transistor output 208. In operation, the RF output signal produced by transistor 202 appears at transistor output 208. Harmonic termination 204 generally includes an input inductance element 210 (labeled L3), an output inductance element 212 (labeled L4), a shunt circuit 214, and a tank circuit 216. Shunt circuit 214 is coupled between a connection node 218 of harmonic termination 204 and a reference potential, for example, ground. Tank circuit 216 is coupled between connection node 218 and output inductance element 212; in this example, tank circuit 216 and output inductance element 212 are connected at a tank output node 219. In this example embodiment, shunt circuit 214 includes an inductance element 220 (labeled L1) in series with a capacitance element 222 (labeled C1), where one end of inductance element 220 is coupled to connection node 218, and one end of capacitance element 222 is coupled to ground. In this example embodiment, tank circuit 216 includes an inductance element 224 (labeled L2) in parallel with a capacitance element 226 (labeled C2).

Input inductance element 210 may be coupled to transistor output 208 such that shunt circuit 214 and tank circuit 216 can receive the RF output signal generated by transistor 202. Input inductance element 210 may be realized as a conductive wire bond having a relatively low inductance that is considered during tuning of harmonic termination 204. Alternatively, input inductance element 210 may be realized as an integrated passive device (“IPD”) inductor formed on the semiconductor substrate, a discrete component mounted on the semiconductor substrate, or as any suitable on-chip inductor.

In a practical embodiment, the on-chip harmonic termination 204 may include a termination output 228 for providing a terminated RF output signal that is based upon the RF output signal provided at transistor output 208. An electronic device, system, or subsystem that includes transistor 202 and harmonic termination 204 may include an off-chip contact 230, which may be realized as a conductive bond pad on a printed circuit board, a terminal or a pin on a separate integrated circuit chip, or the like. In operation, off-chip contact 230 is configured to receive the terminated RF output signal generated by harmonic termination 204. Off-chip contact 230 may be coupled to an off-chip matching circuit or network as described above in connection with electronic device 100. Alternatively, off-chip contact 230 may be coupled to any suitable off-chip component as necessary for the particular application. In one example implementation, harmonic termination 204 uses output inductance element 212 for coupling to off-chip contact 230. In this regard, output inductance element 212 may be realized as a conductive wire bond having a relatively low inductance that is considered during tuning of harmonic termination 204. Such a conductive wire bond is considered to be “formed on” or “located on” the semiconductor substrate for purposes of this description. Alternatively, output inductance element 212 may be realized as an IPD inductor formed on the semiconductor substrate, a discrete component mounted on the semiconductor substrate, or as any suitable on-chip inductor.

In one preferred embodiment, inductance element 220, capacitance element 222, inductance element 224, and capacitance element 226 are all tunable, on-chip components that facilitate tuning of harmonic termination 204 for the desired operating frequencies. As mentioned above, a properly tuned harmonic termination will provide a short-circuit termination for even-numbered harmonics of the RF output signal, and provide an open-circuit termination for odd-numbered harmonics of the RF output signal. These tunable elements can be realized with selectable, variable, adjustable, or otherwise configurable on-chip structures. For example, inductance element 220 may comprise one or more IPD inductors or discrete components that are selectable, variable, or tunable to provide a desired amount of inductance for shunt circuit 214, capacitance element 222 may comprise one or more IPD capacitors or discrete components that are selectable, variable, or tunable to provide a desired amount of capacitance for shunt circuit 214, inductance element 224 may comprise one or more IPD inductors or discrete components that are selectable, variable, or tunable to provide a desired amount of inductance for tank circuit 216, and capacitance element 226 may comprise one or more IPD capacitors or discrete components that are selectable, variable, or tunable to provide a desired amount of capacitance for tank circuit 216. Thus, even though FIG. 2 depicts these inductance and capacitance elements as single components, in practice each schematically depicted component may be realized with more than one physical component.

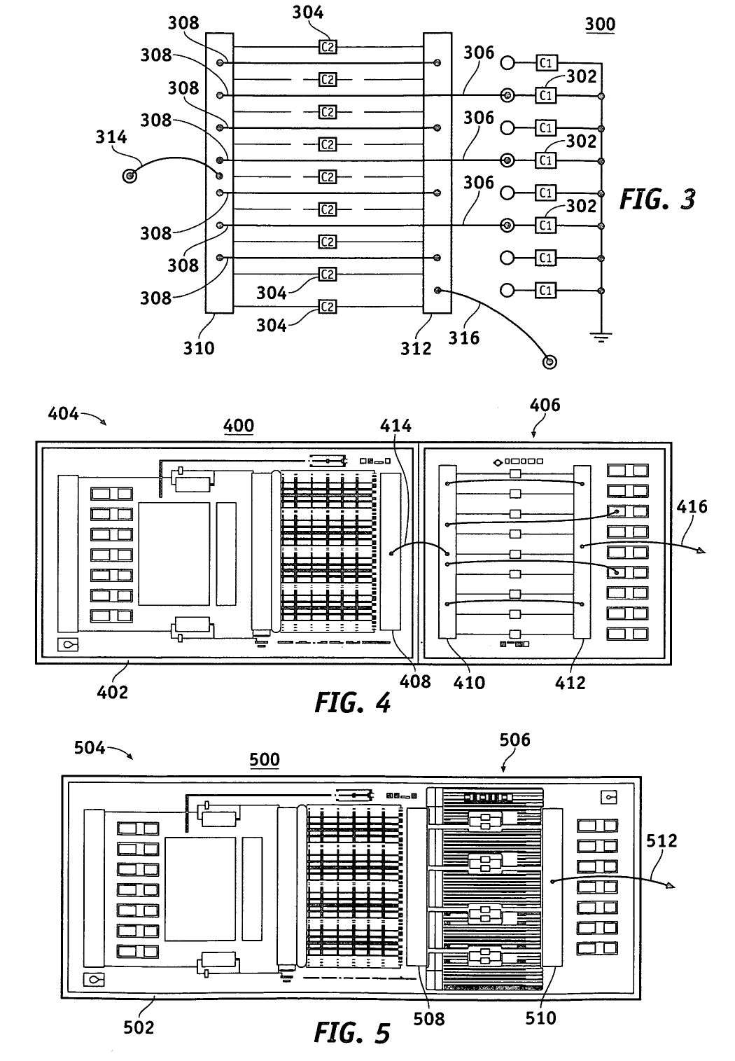

FIG. 3 is a top view of an on-chip harmonic termination layout 300 configured in accordance with an example embodiment of the invention. Layout 300 may be utilized in a practical implementation of harmonic termination 104 and/or in a practical implementation of harmonic termination 204. In this regard, unless otherwise indicated, all of the features shown in FIG. 3 are preferably formed on a common semiconductor substrate as on-chip elements. For convenience, the following description of harmonic termination layout 300 refers to elements shown in FIG. 2. Briefly, harmonic termination layout 300 represents a practical embodiment where capacitance element 222 comprises a first set of one or more parallel capacitors 302, capacitance element 226 comprises a second set of one or more parallel capacitors 304, inductance element 220 comprises a first set of one or more conductive wire bonds 306, and inductance element 224 comprises a second set of one or more conductive wire bonds 308.

Harmonic termination layout 300 includes a first conductive bus bar 310, which corresponds to connection node 218 in this example, and a second conductive bus bar 312, which corresponds to tank output node 219 in this example. FIG. 3 also depicts a conductive wire bond 314, which serves as input inductance element 210, and a conductive wire bond 316, which serves as output inductance element 212. In this example, inductance element 220 is realized as a set of three conductive wire bonds 306 coupled between first bus bar 310 and the parallel bank of capacitors 302, while inductance element 224 is realized as a set of four conductive wire bonds 308 coupled between first bus bar 310 and second bus bar 312. Thus, conductive wire bonds 308 and capacitors 304 are connected in parallel and are coupled across first bus bar 310 and second bus bar 312.

The general tuning process for the harmonic termination may utilize suitable RF and/or microwave tuning techniques to achieve the desired open circuit and short circuit functionality for the desired harmonic frequencies. In a practical embodiment, the harmonic termination can be tuned using simulation techniques to arrive at the desired values for the various inductance and capacitance elements. Thereafter, the inductance and capacitance elements can be tuned, selected, or adjusted in an appropriate manner. Tuning techniques for an example embodiment are described below.

In practice, inductance element 224 is tuned by selecting the number of conductive wire bonds 308 to be coupled between first bus bar 310 and second bus bar 312. Generally, the amount of inductance will be proportional to the number of conductive wire bonds 308. In addition, the inductive characteristics of the conductive wire itself may be considered in connection with the tuning of inductance element 220. Likewise, inductance element 220 can be tuned by selecting the number of conductive wire bonds 306 to be coupled between first bus bar 310 and capacitance element 222. As depicted in FIG. 3, each capacitor 302 may have an associated contact point for receiving a conductive wire bond, and establishing the wire bond connection inserts the respective capacitor 302 into the harmonic termination circuit. Alternatively, the contact points may be connected by a common bus bar and the leads to designated capacitors 302 may be severed to remove those capacitors 302 from the harmonic termination circuit.

In practice, capacitance element 226 is tuned by selecting the number of capacitors 304 to be coupled between first bus bar 310 and second bus bar 312. The capacitance of each capacitor 304 may be the same, or capacitors 304 may have different capacitance values as needed to provide flexible adjustment capability. In this example, harmonic termination layout 300 is initially fabricated such that all capacitors 304 are coupled between first bus bar 310 and second bus bar 312. Capacitance element 226 is tuned by removing certain capacitors 304 from the harmonic termination circuit. Such removal can be achieved by severing the leads to capacitors 304 (as depicted in FIG. 3), by removing capacitors 304, or the like. Capacitance element 222 can be tuned in a similar manner (as described in the immediately preceding paragraph). Alternatively, in the example shown in FIG. 3, harmonic termination layout 300 is initially fabricated such that one end of each capacitor 304 is left floating, i.e., capacitors 302 are not initially connected to the harmonic termination circuit. In this case, capacitance element 222 is tuned by inserting certain capacitors 304 into the harmonic termination circuit. Such insertion can be achieved, for example, by installing conductive wire bonds 306 as described above.

FIG. 4 is a top view of an RF electronic device 400 configured in accordance with an example embodiment of the invention. FIG. 4 represents one example layout or pattern associated with a practical electronic device. Some of the functions and features of electronic device 400 may be similar to those described above in connection with FIGS. 1-3, and such common functions and features will not be redundantly described in detail herein. Electronic device 400 generally includes a semiconductor substrate 402, a transistor 404 formed on semiconductor substrate 402, and a harmonic termination 406 formed on semiconductor substrate 402. In other words, semiconductor substrate 402 is common to both transistor 404 and harmonic termination 406, and the bulk of transistor 404 and harmonic termination 406 are fabricated together using the same semiconductor manufacturing process technology.

Transistor 404 includes a transistor output node 408, which is realized as a conductive bus bar in this example. Harmonic termination 406 (which is similar to harmonic termination 300) includes a first connection node 410 and a second connection node 412. In this example, first connection node 410 is realized as a first conductive bus bar and second connection node 412 is realized as a second conductive bus bar. As described above, first connection node 410 corresponds to the input node of the resonant tank circuit of harmonic termination 406, and second connection node 412 corresponds to the output node of the resonant tank circuit. Electronic device 400 utilizes one or more conductive wire bonds 414 (or any suitable conductive element) to establish an electrical connection between transistor output node 408 and first connection node 410. In practice, this conductive wire bond 414 also represents an input inductance element that influences the tuning of harmonic termination 406. Electronic device 400 may also employ one or more conductive wire bonds 416 (or any suitable conductive element) to couple second connection node 412 to an off-chip contact, another on-chip feature or element, an off-chip feature or element, or the like. In practice, this conductive wire bond 416 also represents an output inductance element that influences the tuning of harmonic termination 406.

The tuning of harmonic termination 406 may be carried out in the manner described above.

FIG. 5 is a top view of an RF electronic device 500 configured in accordance with another example embodiment of the invention. FIG. 5 represents another example layout or pattern associated with a practical electronic device. Some of the functions and features of electronic device 500 may be similar to those described above in connection with FIGS. 1-4, and such common functions and features will not be redundantly described in detail herein. Electronic device 500 generally includes a semiconductor substrate 502, a transistor 504 formed on semiconductor substrate 502, and a harmonic termination 506 formed on semiconductor substrate 502. In other words, semiconductor substrate 502 is common to both transistor 504 and harmonic termination 506, and the bulk of transistor 504 and harmonic termination 506 are fabricated together using the same semiconductor manufacturing process technology. Harmonic termination 506 is configured differently than harmonic termination 406; the particular configuration of a practical harmonic termination may vary to suit the operating frequency and/or other operating parameters of the electronic device.

Transistor 504 includes a transistor output node, which is realized as a conductive bus bar 508 in this example. Harmonic termination 506 includes a first connection node, which is realized as conductive bus bar 508 in this example. In other words, conductive bus bar 508 corresponds to both the output of transistor 504 and the input of harmonic termination 506. Harmonic termination 506 also includes a second connection node, which is realized as another conductive bus bar 510 in this example. As described above, conductive bus bar 508 corresponds to the input node of the resonant tank circuit of harmonic termination 506, and second conductive bus bar 510 corresponds to the output node of the resonant tank circuit.

Due to the shared conductive bus bar 508, electronic device 500 need not employ any wire bonds or conductive links to establish connectivity between transistor 504 and harmonic termination 506. Rather, the output section of transistor 504, the input section of harmonic termination 506, and conductive bus bar 508 are fabricated together to form a common node. Consequently, conductive bus bar 508 may be considered to be an input inductance element (i.e., an inductive bus bar) having an inductance that influences the tuning of harmonic termination 506. Electronic device 500 may also employ one or more conductive wire bonds 512 (or any suitable conductive element) to couple conductive bus bar 510 to an off-chip contact, another on-chip feature or element, an off-chip feature or element, or the like. In practice, this conductive wire bond 510 also represents an output inductance element that influences the tuning of harmonic termination 506.

The tuning of harmonic termination 506 may be carried out in the manner described above.

In summary, systems, devices, and methods configured in accordance with example embodiments of the invention relate to:

An RF electronic device comprising a semiconductor substrate, a transistor formed on said semiconductor substrate, said transistor having a transistor output node for an RF output signal, and a harmonic termination formed on said semiconductor substrate, said harmonic termination having a termination input node coupled to said transistor output node, and said harmonic termination being configured to provide a short-circuit termination for even harmonics of said RF output signal and to provide an open-circuit termination for odd harmonics of said RF output signal. The harmonic termination may comprise an input inductance element coupled to said transistor output node. The input inductance element may comprise a conductive wire bond. The input inductance element may comprise an IPD inductor formed on said semiconductor substrate. The harmonic termination may comprise an output inductance element for coupling to an off-chip component. The output inductance element may comprise a conductive wire bond. The output inductance element may comprise an IPD inductor formed on said semiconductor substrate. The harmonic termination may comprise a connection node, a shunt circuit coupled between said connection node and a reference potential, and a tank circuit coupled to said connection node. The shunt circuit may comprise a first inductance element in series with a first capacitance element, and said tank circuit may comprise a second inductance element in parallel with a second capacitance element. The RF electronic device may further comprise a first bus bar corresponding to said connection node, and a second bus bar corresponding to a tank output node for said tank circuit, wherein said first inductance element comprises a first set of one or more conductive wire bonds coupled between said first bus bar and said first capacitance element, and said second inductance element comprises a second set of one or more conductive wire bonds coupled between said first bus bar and said second bus bar. The first inductance element may comprise a first IPD inductor formed on said semiconductor substrate, and said second inductance element may comprise a second IPD inductor formed on said semiconductor substrate. The first capacitance element may comprise a first IPD capacitor formed on said semiconductor substrate, and said second capacitance element may comprise a second IPD capacitor formed on said semiconductor substrate. The first capacitance element may comprise a first set of one or more parallel capacitors, and said second capacitance element may comprise a second set of one or more parallel capacitors.

An RF electronic device comprising a semiconductor substrate, a transistor formed on said semiconductor substrate, said transistor having a transistor output for an RF output signal, and a tunable harmonic termination formed on said semiconductor substrate, said tunable harmonic termination having a termination input for receiving said RF output signal and a termination output for a terminated RF output signal, and said tunable harmonic termination being configured to provide a short-circuit termination for even harmonics of said RF output signal and to provide an open-circuit termination for odd harmonics of said RF output signal. The RF electronic device may further comprise an off-chip contact coupled to said termination output, said off-chip contact being configured to receive said terminated RF output signal. The RF electronic device may further comprise an off-chip matching circuit coupled to said off-chip contact. The tunable harmonic termination may comprise an output inductance element for coupling to said off-chip contact. The RF electronic device may further comprise an inductive bus bar formed on said semiconductor substrate, said inductive bus bar corresponding to both said termination input and said transistor output.

An RF electronic device comprising, a semiconductor substrate, a transistor formed on said semiconductor substrate, said transistor being configured to generate an RF output signal, and a tunable harmonic termination formed on said semiconductor substrate and coupled to said transistor, said harmonic termination being configured to receive said RF output signal, to provide a short-circuit termination for even harmonics of said RF output signal, and to provide an open-circuit termination for odd harmonics of said RF output signal, said tunable harmonic termination comprising a connection node, a shunt circuit coupled between said connection node and a reference potential, said shunt circuit comprising a first selectable inductance element in series with a first tunable capacitance element, and a tank circuit coupled to said connection node, said tank circuit comprising a second selectable inductance element in parallel with a second tunable capacitance element. The first selectable inductance element may comprise a first set of one or more conductive wire bonds coupled between said connection node and said first tunable capacitance element, and said second selectable inductance element may comprise a second set of one or more conductive wire bonds coupled across said second tunable capacitor element. The first tunable capacitance element may comprise a first set of one or more parallel capacitors coupled between said reference potential and said first selectable inductance element, and said second tunable capacitance element may comprise a second set of one or more parallel capacitors coupled across said second selectable inductance element.

While at least one example embodiment has been presented in the foregoing detailed description, it should be appreciated that a vast number of variations exist. It should also be appreciated that the example embodiment or embodiments described herein are not intended to limit the scope, applicability, or configuration of the invention in any way. Rather, the foregoing detailed description will provide those skilled in the art with a convenient road map for implementing the described embodiment or embodiments. It should be understood that various changes can be made in the function and arrangement of elements without departing from the scope of the invention as set forth in the appended claims and the legal equivalents thereof.

What is claimed is:

1. A radio frequency (“RF”) electronic device comprising:
a semiconductor substrate;
a transistor circuit formed on said semiconductor substrate, said transistor circuit having a transistor output node for an RF output signal; and
a harmonic termination formed on said semiconductor substrate, said harmonic termination having a termination input node coupled to said transistor output node, and said harmonic termination being configured to provide a short-circuit termination for even harmonics of said RF output signal and to provide an open-circuit termination for odd harmonics of said RF output signal.

2. An RF electronic device according to claim 1, said harmonic termination comprising an input inductance element coupled to said transistor output node.

3. An RF electronic device according to claim 2, said input inductance element comprising a conductive wire bond.

4. An RF electronic device according to claim 2, said input inductance element comprising an integrated passive device (“IPD”) inductor formed on said semiconductor substrate.

5. An RF electronic device according to claim 1, said harmonic termination comprising an output inductance element for coupling to an off-chip component.

6. An RF electronic device according to claim 5, said output inductance element comprising a conductive wire bond.

7. An RF electronic device according to claim 5, said output inductance element comprising an integrated passive device (“IPD”) inductor formed on said semiconductor substrate.

8. An RF electronic device according to claim 1, said harmonic termination comprising:
a connection node;
a shunt circuit coupled between said connection node and a reference potential; and
a tank circuit coupled to said connection node.

9. An RF electronic device according to claim 8, said shunt circuit comprising a first inductance element in series with a first capacitance element, and said tank circuit comprising a second inductance element in parallel with a second capacitance element.

10. An RF electronic device according to claim 9, further comprising:
a first bus bar corresponding to said connection node; and
a second bus bar corresponding to a tank output node for said tank circuit; wherein
said first inductance element comprises a first set of one or more conductive wire bonds coupled between said first bus bar and said first capacitance element; and
said second inductance element comprises a second set of one or more conductive wire bonds coupled between said first bus bar and said second bus bar.

11. An RF electronic device according to claim 9, said first inductance element comprising a first integrated passive device (“IPD”) inductor formed on said semiconductor substrate, and said second inductance element comprising a second IPD inductor formed on said semiconductor substrate.

12. An RF electronic device according to claim 9, said first capacitance element comprising a first integrated passive device (“IPD”) capacitor formed on said semiconductor substrate, and said second capacitance element comprising a second IPD capacitor formed on said semiconductor substrate.

13. An RF electronic device according to claim 9, said first capacitance element comprising a first set of one or more parallel capacitors, and said second capacitance element comprising a second set of one or more parallel capacitors.

14. A radio frequency (“RF”) electronic device comprising:
a semiconductor substrate;
a transistor circuit formed on said semiconductor substrate, said transistor circuit having a transistor output for an RF output signal; and
a tunable harmonic termination formed on said semiconductor substrate, said tunable harmonic termination having a termination input for receiving said RF output signal and a termination output for a terminated RF output signal, and said tunable harmonic termination being configured to provide a short-circuit termination for even harmonics of said RF output signal and to provide an open-circuit termination for odd harmonics of said RF output signal.

15. An RF electronic device according to claim 14, further comprising an off-chip contact coupled to said termination output, said off-chip contact being configured to receive said terminated RF output signal.

16. An RF electronic device according to claim 15, further comprising an off-chip matching circuit coupled to said off-chip contact.

17. An RF electronic device according to claim 15, said tunable harmonic termination comprising an output inductance element for coupling to said off-chip contact.

18. An RF electronic device according to claim 14, further comprising an inductive bus bar formed on said semiconductor substrate, said inductive bus bar corresponding to both said termination input and said transistor output.

19. A radio frequency (“RF”) electronic device comprising:
a semiconductor substrate;
a transistor circuit formed on said semiconductor substrate, said transistor circuit being configured to provide an RF output signal; and
a tunable harmonic termination formed on said semiconductor substrate and coupled to said transistor circuit, said harmonic termination being configured to receive said RF output signal, to provide a short-circuit termination for even harmonics of said RF output signal, and to provide an open-circuit termination for odd harmonics of said RF output signal, said tunable harmonic termination comprising:
a connection node;
a shunt circuit coupled between said connection node and a reference potential, said shunt circuit comprising a first selectable inductance element in series with a first tunable capacitance element; and
a tank circuit coupled to said connection node, said tank circuit comprising a second selectable inductance element in parallel with a second tunable capacitance element.

20. An RF electronic device according to claim 19, wherein:
said first selectable inductance element comprises a first set of one or more conductive wire bonds coupled between said connection node and said first tunable capacitance element; and
said second selectable inductance element comprises a second set of one or more conductive wire bonds coupled across said second tunable capacitor element.

21. An RF electronic device according to claim 19, wherein:
said first tunable capacitance element comprises a first set of one or more parallel capacitors coupled between said reference potential and said first selectable inductance element; and
said second tunable capacitance element comprises a second set of one or more parallel capacitors coupled across said second selectable inductance element.
